(19) United States
(12) Patent Application Publication
(10) Pub. No.: US 2002/0086111 A1
(43) Pub. Date: Jul. 4, 2002

(54) Method of forming refractory metal nitride layers using chemisorption techniques

(76) Inventors: Jeong Soo Byun, Cupertino, CA (US); Alfred Mak, Union City, CA (US)

Correspondence Address: Patent Counsel, APPLIED MATERIALS, INC., P.O. Box 450-A, Santa-Clara, CA, 95052, US

(21) Appl. No.: 09/754,230

(22) Filed: Jan. 3, 2001

(51) Int. Cl. B32B 9/00; H01L 21/44; H01L 29/40; H01L 23/48; C23C 16/34; C23C 16/22; C23C 16/00

(52) U.S. Cl. 427/255.394; 428/698; 428/336; 438/655; 438/656; 257/768; 438/682; 438/683; 427/255.28

(57) ABSTRACT

A method of forming a refractory metal nitride layer for integrated circuit fabrication is disclosed. In one embodiment, the refractory metal nitride layer is formed by chemisorbing monolayers of a hydrazine-based compound and one or more refractory metal compounds onto a substrate. In an alternate embodiment, the refractory metal nitride layer has a composite structure, which is composed of two or more refractory metals. The composite refractory metal nitride layer is formed by sequentially chemisorbing monolayers of a hydrazine-based compound and two or more refractory metal compounds on a substrate.

### BACKGROUND OF THE DISCLOSURE

1. Field of the Invention

The present invention relates to the formation of refractory metal nitride layers and, more particularly to refractory metal nitride layers formed using chemisorption techniques.

2. Description of the Background Art

In the manufacture of integrated circuits, barrier layers are often used to inhibit the diffusion of metals and other impurities into regions underlying such barrier layers. These underlying regions may include transistor gates, capacitor dielectric, semiconductor substrates, metal lines, as well as many other structures that appear in integrated circuits.

For the current subhalf-micron (<0.5 μm) generation of semiconductor devices, any microscopic reaction at an interface between interconnection layers can cause degradation of the resulting integrated circuits (e. g., increase the resistivity of the interconnection layers). Consequently, barrier layers have become a critical component for improving the reliability of interconnect metallization schemes.

Compounds of refractory metals such as, for example, nitrides, borides, and carbides have been suggested as diffusion barriers because of their chemical inertness and low resistivities (e. g., resistivities typically less than about 500 μΩ-cm). In particular, refractory metal nitrides, such as, for example, titanium nitride (TiN) have been suggested for use as a barrier material since layers formed thereof generally have low resistivities, and are chemically stable at high temperatures.

Refractory metal nitride barrier layers are typically formed using physical vapor deposition (PVD) or chemical vapor deposition (CVD) techniques. For example, titanium metal may be sputtered in a nitrogen (N₂) atmosphere to form titanium nitride (TiN) using PVD techniques, or titanium tetrachloride (TiCl₄) may be reacted with ammonia (NH₃) to form TiN using CVD techniques. However, both PVD and/or CVD techniques for forming refractory metal nitride layers typically require process temperatures in excess of 600° C. Such high process temperatures may affect other material layers that are in contact with the refractory metal nitride layers. For example, refractory metal nitride layers are often deposited onto buried semiconductor junctions. At high temperatures dopants in the semiconductor junctions may diffuse out of the buried junctions, potentially changing the characteristics thereof.

Additionally when chlorine-based chemistries are used to form the refractory metal nitride layers, such nitride layers typically have a high chlorine content. A high chlorine content is undesirable because chlorine may migrate from the refractory metal nitride barrier layer into adjacent material layers (e.g. interconnection layers), which can increase the contact resistance of such layers, potentially changing the characteristics of integrated circuits made therefrom.

Therefore, a need exists in the art for reliable refractory metal nitride layers for integrated circuit fabrication. Particularly desirable would be refractory metal nitride layers that are formed at low temperatures.

### SUMMARY OF THE INVENTION

Refractory metal nitride layers for integrated circuit fabrication are provided. In one embodiment the refractory metal nitride layer comprises one refractory metal. The refractory metal nitride layer may be formed by sequentially chemisorbing alternating monolayers of a refractory metal compound and a hydrazine-based compound onto a substrate. The term monolayer as used in this disclosure also includes a few atomic layers (e. g., less than 5 atomic layers) of a compound as well as sub-atomic layers (e. g., less than one atomic layer) of a compound.

In an alternate embodiment, a composite refractory metal nitride layer is formed. The composite refractory metal nitride layer comprises two or more refractory metals. The composite refractory metal nitride layer may be formed by sequentially chemisorbing monolayers of a hydrazine-based compound and two or more refractory metal compounds onto a substrate.

The refractory metal nitride layer is compatible with integrated circuit fabrication processes. In one integrated circuit fabrication process, a refractory metal nitride barrier layer is formed by sequentially chemisorbing alternating monolayers of a hydrazine-based compound and one refractory metal compound on a substrate. Thereafter, one or more metal layers are deposited on the refractory metal nitride barrier layer to form an interconnect structure.

In another integrated circuit fabrication process, a composite refractory metal nitride barrier layer is formed by sequentially chemisorbing monolayers of a hydrazine-based compound and two or more refractory metal compounds on a substrate. Thereafter, one or more metal layers are deposited on the refractory metal nitride barrier layer to form an interconnect structure.

### BRIEF DESCRIPTION OF THE DRAWINGS

The teachings of the present invention can be readily understood by considering the following detailed description in conjunction with the accompanying drawings, in which:

FIG. 1 depicts a schematic illustration of an apparatus that can be used for the practice of embodiments described herein;

FIGS. 2a-2c depict cross-sectional views of a substrate structure at different stages of integrated circuit fabrication incorporating a refractory metal nitride layer;

FIGS. 3a-3d depict cross-sectional views of a substrate undergoing a first sequential chemisorption process of a hydrazine-based compound and one refractory metal compound to form a refractory metal nitride layer;

FIGS. 4a-4f depict cross-sectional views of a substrate undergoing a second sequential chemisorption process of a hydrazine-based compound and two or more refractory metal compounds to form a composite refractory metal nitride layer;

FIGS. 5a-5d depict cross-sectional views of a substrate undergoing a third sequential chemisorption process of a hydrazine-based compound and two or more refractory metal compounds to form a composite refractory metal nitride layer; and

FIGS. 6a-6c depict cross-sectional views of a substrate structure at different stages of integrated circuit fabrication incorporating more than one refractory metal nitride barrier layer.

### DETAILED DESCRIPTION

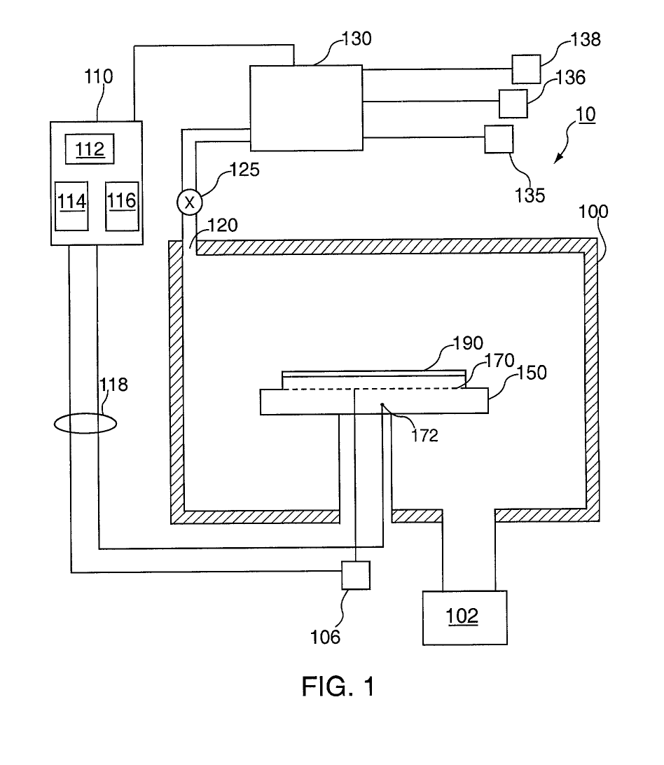

FIG. 1 depicts a schematic illustration of a wafer processing system 10 that can be used to form refractory metal nitride barrier layers in accordance with embodiments described herein. The system 10 comprises a process chamber 100, a gas panel 130, a control unit 110, along with other hardware components such as power supplies 106 and vacuum pumps 102. The salient features of process chamber 100 are briefly described below.

Chamber 100

The process chamber 100 generally houses a support pedestal 150, which is used to support a substrate such as a semiconductor wafer 190 within the process chamber 100. Depending on the specific process, the semiconductor wafer 190 can be heated to some desired temperature prior to layer formation.

In chamber 100, the wafer support pedestal 150 is heated by an embedded heater 170. For example, the pedestal 150 may be resistively heated by applying an electric current from an AC power supply 106 to the heater element 170. The wafer 190 is, in turn, heated by the pedestal 150, and can be maintained within a desired process temperature range of, for example, about 20° C. to about 600° C.

A temperature sensor 172, such as a thermocouple, is also embedded in the wafer support pedestal 150 to monitor the temperature of the pedestal 150 in a conventional manner. For example, the measured temperature may be used in a feedback loop to control the electric current applied to the heater element 170 by the power supply 106, such that the wafer temperature can be maintained or controlled at a desired temperature that is suitable for the particular process application. The pedestal 150 is optionally heated using radiant heat (not shown).

A vacuum pump 102 is used to evacuate process gases from the process chamber 100 and to help maintain the desired pressure inside the chamber 100. An orifice 120 is used to introduce process gases into the process chamber 100. The dimensions of the orifice 120 are variable and typically depend on the size of the process chamber 100.

The orifice 120 is coupled to a gas panel 130 via a valve 125. The gas panel 130 provides process gases from two or more gas sources 135, 136 to the process chamber 100 through orifice 120 and valve 125. The gas panel 130 also provides a purge gas from a purge gas source 138 to the process chamber 100 through orifice 120 and valve 125.

A control unit 110, such as a computer, controls the flow of various process gases through the gas panel 130 as well as valve 125 during the different steps of a wafer process sequence. Illustratively, the control unit 110 comprises a central processing unit (CPU) 112, support circuitry 114, and memories containing associated control software 116. In addition to the control of process gases through the gas panel 130, the control unit 110 is also responsible for automated control of the numerous steps required for wafer processing—such as wafer transport, temperature control, chamber evacuation, among other steps.

The control unit 110 may be one of any form of general purpose computer processor that can be used in an industrial setting for controlling various chambers and sub-processors. The computer processor may use any suitable memory, such as random access memory, read only memory, floppy disk drive, hard disk, or any other form of digital storage, local or remote. Various support circuits may be coupled to the computer processor for supporting the processor in a conventional manner. Software routines as required may be stored in the memory or executed by a second processor that is remotely located. Bi-directional communications between the control unit 110 and the various components of the wafer processing system 10 are handled through numerous signal cables collectively referred to as signal buses 118, some of which are illustrated in FIG. 1.

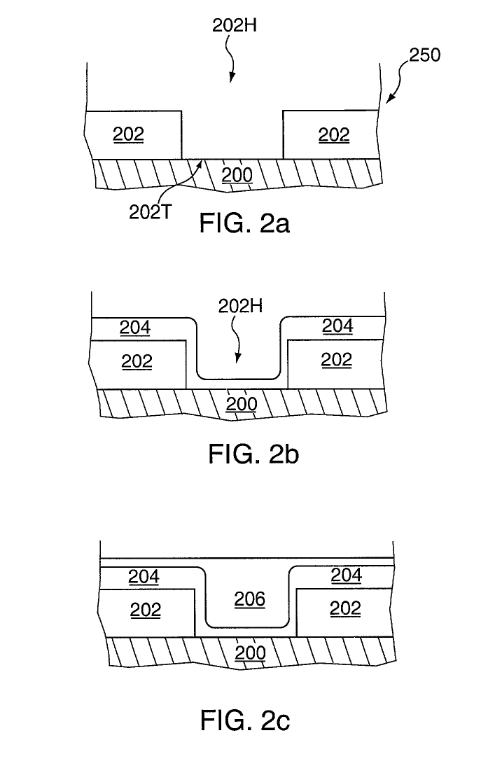

Refractory Metal Nitride Layer Formation FIGS. 2a-2c illustrate one preferred embodiment of refractory metal nitride layer formation for fabrication of an interconnect structure. In general, the substrate 200 refers to any workpiece upon which film processing is performed, and a substrate structure 250 is used to generally denote the substrate 200 as well as other material layers formed on the substrate 200. Depending on the specific stage of processing, the substrate 200 may be a silicon semiconductor wafer, or other material layers which have been formed on the wafer. FIG. 2a, for example, shows a cross-sectional view of a substrate structure 250, having a material layer 202 thereon. In this particular illustration, the material layer 202 may be an oxide (e.g. silicon dioxide). The material layer 202 has been conventionally formed and patterned to provide contact holes 202H extending to the top surface 200T of the substrate 200.

FIG. 2bshows a refractory metal nitride layer 204 conformally formed on the substrate structure 250. The refractory metal nitride layer 204 is formed by chemisorbing monolayers of a hydrazine-based compound and at least one refractory metal compound on a substrate structure 250. The monolayers are chemisorbed by sequentially providing a hydrazine-based compound and one or more refractory metal compounds to a process chamber.

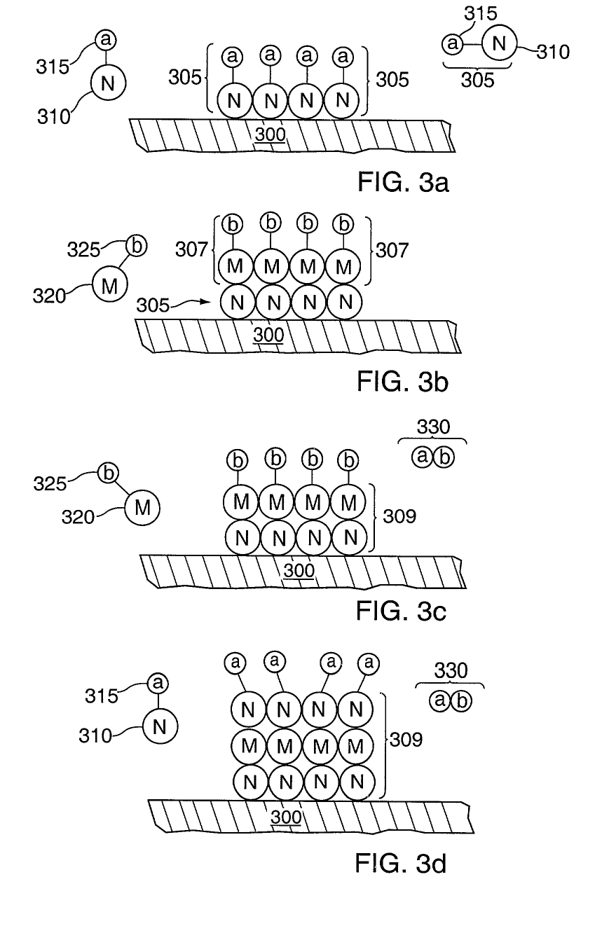

In a first sequential chemisorption process, monolayers of a hydrazine-based compound and one refractory metal compound are alternately chemisorbed on a substrate 300 as shown in FIGS. 3a-3d. FIG. 3a depicts a cross-sectional view of a substrate 300, which may be in a stage of integrated circuit fabrication. A monolayer of a hydrazine-based compound 305 is chemisorbed on the substrate 300 by introducing a pulse of a hydrazine-based gas into a process chamber similar to that shown in FIG. 1. The hydrazine-based compound typically combines nitrogen (N) atoms 310 with one or more reactive species a 315. During refractory metal nitride layer formation, the reactive species a 315 form by-products that are transported from the substrate surface by the vacuum system.

Chemisorption processes used to absorb the monolayer of the hydrazine-based compound 305 are self-limiting, in that only one monolayer may be chemisorbed onto the substrate 300 surface during a given pulse. Only one monolayer of the hydrazine-based compound may be chemisorbed on the substrate because the substrate has a limited surface area. This limited surface area provides a finite number of sites for chemisorbing the hydrazine-based compound. Once the finite number of sites are occupied by the hydrazine-based compound, further chemisorption of any hydrazine-based compound will be blocked.

Suitable hydrazine-based compounds may include, for example, hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃) ₆C₂N₂), ethylazide (C₂H₅N₃), as well as combinations thereof.

After the monolayer of the hydrazine-based compound is chemisorbed onto the substrate 300, excess hydrazine-based compound is removed from the process chamber by introducing a pulse of a purge gas thereto. Purge gases such as, for example helium (He), argon (Ar), nitrogen (N₂), and hydrogen (H₂), among others may be used.

After the process chamber has been purged, a pulse of one refractory metal compound is introduced into the process chamber. Referring to FIG. 3b, a monolayer of the refractory metal compound 307 is chemisorbed on the monolayer of hydrazine-based compound 305. The refractory metal compound typically combines refractory metal atoms M 320 with one or more reactive species b 325.

The chemisorbed monolayer of the refractory metal compound 307 reacts with the monolayer of hydrazine-based compound 305 to form a refractory metal nitride layer 309, as shown in FIG. 3c. The reactive species a 315 and b 325 form by-products ab 330 that are transported from the substrate surface by the vacuum system. The reaction of the refractory metal compound 307 with the hydrazine-based compound 305 is self-limited, since only one monolayer of the hydrazine-based compound was chemisorbed onto the substrate surface.

The refractory metal compound may include refractory metals such as, for example, titanium (Ti), tungsten (W), tantalum (Ta), zirconium (Zr), hafnium (Hf), molybdenum (Mo), niobium (Nb), vanadium (V), and chromium (Cr), among others combined with reactive species such as, for example chlorine (Cl), fluorine (F), bromine (Br), and iodine (I). Titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (TiI₄), titanium bromide (TiBr₄), among others may be used as the refractory metal compound. Suitable refractory metal compounds may also include metal organic compounds such as, for example, tetrakis(dimethylamido)titanium (TDMAT) and pentakis(dimethylamido) tantalum (PDMAT), tetrakis(diethylamido)titanium (TDEAT), tungsten hexacarbonyl (W(CO) ₆), tungsten hexachloride (WCl₆), tetrakisdiethylamido)titanium (TDEAT), pentakisdiethylamido)tantalum (PDEAT), among others.

After the monolayer of the refractory metal compound is chemisorbed on the monolayer of hydrazine-based compound 305, any excess refractory metal compound is removed from the process chamber by introducing another pulse of the purge gas therein. Thereafter, as shown in FIG. 3d, the refractory metal nitride layer deposition sequence of alternating monolayers of the hydrazine-based compound and the refractory metal compound are repeated until a desired refractory metal nitride layer 309 thickness is achieved.

In FIGS. 3a-3d, refractory metal nitride layer formation is depicted as starting with the chemisorption of a monolayer of a hydrazine-based compound on the substrate followed by a monolayer of a refractory metal compound. Alternatively, the nitride layer formation may start with the chemisorption of a monolayer of a refractory metal compound on the substrate followed by a monolayer of the hydrazine-based compound.

The pulse time for each pulse of the hydrazine-based compound, the refractory metal compound, and the purge gas is variable and depends on the volume capacity of the deposition chamber as well as the vacuum system coupled thereto. Similarly, the time between each pulse is also variable and depends on the volume capacity of the process chamber as well as the vacuum system coupled thereto.

In general, the alternating monolayers may be chemisorbed at a substrate temperature between about 20° C. and 600° C., and a chamber pressure less than about 100 torr. A pulse time of less than about 5 seconds for hydrazine-based compounds, and a pulse time of less than about 2 seconds for the refractory metal compounds are typically sufficient to chemisorb the alternating monolayers that comprise the refractory metal nitride layer on the substrate. A pulse time of less than about 2 seconds for the purge gas is typically sufficient to remove the reaction by-products as well as any residual materials remaining in the process chamber.

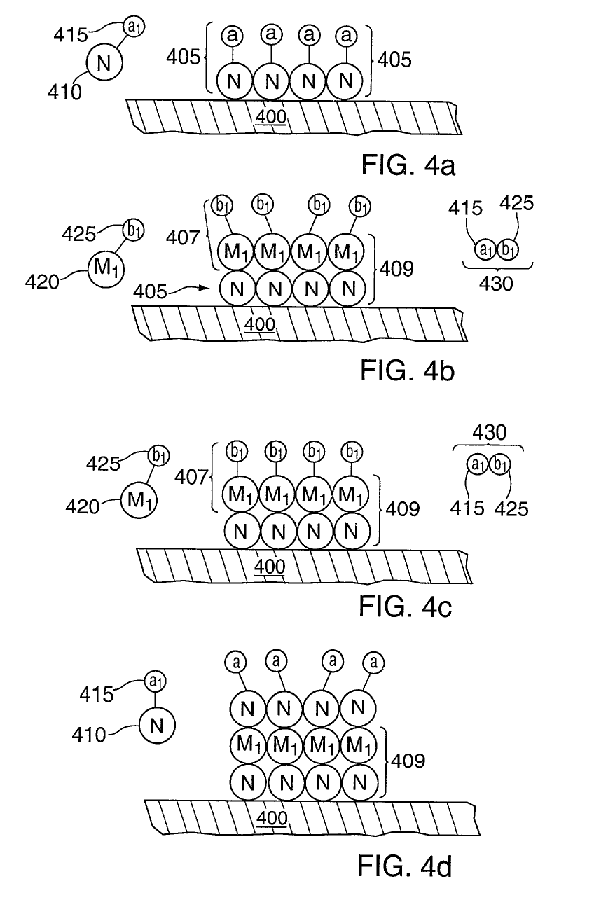

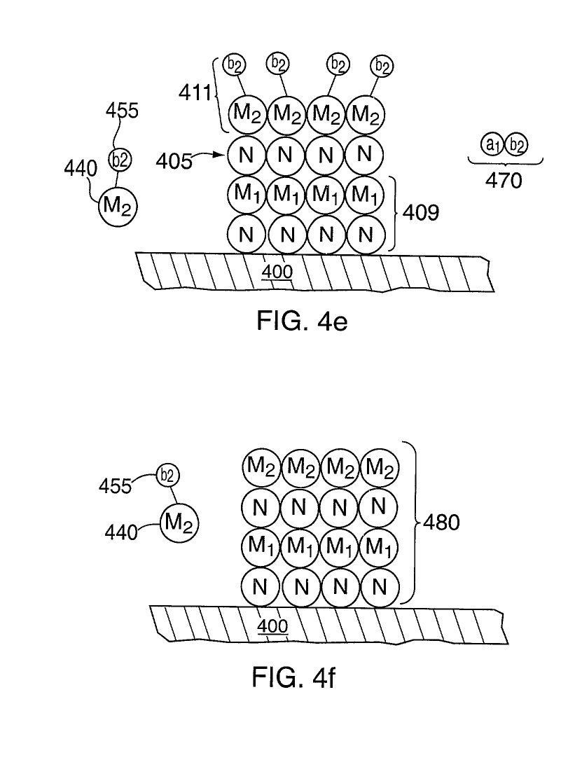

In a second chemisorption process, a hydrazine-based compound and two or more refractory metal compounds are sequentially chemisorbed on a substrate to form a composite refractory metal nitride layer, as shown in FIGS. 4a-4f. FIG. 4a depicts a cross-sectional view of a substrate 400, which may be in a stage of integrated circuit fabrication. A self-limiting monolayer of a hydrazine-based compound 405 is chemisorbed on the substrate 400 by introducing a pulse of a hydrazine-based compound into a process chamber similar to that shown in FIG. 1 according to the process conditions described above with reference to FIGS. 3a-3d. The hydrazine-based compound combines nitrogen atoms (N) 410 with one or more reactive species a₁ 415.

After the monolayer of the hydrazine-based compound 405 is chemisorbed onto the substrate 400, excess hydrazine-based compound is removed from the process chamber by introducing a pulse of a purge gas thereto.

Referring to FIG. 4b, after the process chamber has been purged, a pulse of a first refractory metal compound M₁b₁, 407 is introduced into the process chamber. A layer of the first refractory metal compound 407 is chemisorbed on the monolayer of hydrazine-based compound 405. The first refractory metal compound typically combines refractory metal atoms M₁ 420 with one or more reactive species b₁ 425.

The chemisorbed monolayer of the first refractory metal compound 407 reacts with the monolayer hydrazine-based compound 405 to form a refractory metal nitride layer 409, as shown in FIG. 4c. The reactive species a₁415 and b₁ 425 form by-products a₁b₁430 that are transported from the substrate surface by the vacuum system.

After the monolayer of the first refractory metal compound 407 is chemisorbed onto the monolayer of the hydrazine-based compound 405, excess first refractory metal compound M₁b₁is removed from the process chamber by introducing a pulse of the purge gas therein.

Thereafter, a pulse of the hydrazine-based compound is introduced into the process chamber. A second monolayer of the hydrazine-based compound 405 is chemisorbed on the monolayer of first refractory metal compound 407, as shown in FIG. 4d. The chemisorbed monolayer of the hydrazine-based compound 405 reacts with the monolayer of first refractory metal compound 407 to form the refractory metal nitride layer. The reactive species a₁ 415 and b₁ 425 form by-products a₁b₁ 430 that are transported from the substrate surface by the vacuum system.

After the monolayer of the hydrazine-based compound 405 is chemisorbed on the monolayer of first refractory metal compound 407, excess hydrazine-based compound is removed from the process chamber by introducing a pulse of a purge gas thereto.

Referring to FIG. 4e, after the process chamber has been purged, a pulse of a second refractory metal compound M₂b₂is introduced into the process chamber. A layer of the second refractory metal compound 411 is chemisorbed on the monolayer of the hydrazine-based compound 405. The second refractory metal compound typically combines refractory metal atoms M₂ 440 with one or more reactive species b₂ 455.

The chemisorbed monolayer of the second refractory metal compound 411 reacts with the monolayer of hydrazine-based compound 405, as shown in FIG. 4f to form a composite refractory metal nitride layer 480. The reactive species b₂ 455 and a₁ 415 form by-products a₁b₂ 470 that are transported from the substrate surface by the vacuum system.

After the monolayer of the second refractory metal compound 411 is chemisorbed on the second monolayer of the hydrazine-based compound 405, excess second refractory metal compound M₂b₂ is removed from the process chamber by introducing a pulse of the purge gas therein.

Thereafter, the refractory metal nitride layer deposition sequence of alternating monolayers of the hydrazine-based compound and the two refractory metal compounds M₁b₁ and M₂b₂ are repeated until a desired refractory metal nitride layer thickness is achieved.

In FIGS. 4a-4f, refractory metal nitride layer formation is depicted as starting with the chemisorption of a monolayer of a hydrazine-based compound on the substrate followed by a monolayer of a first refractory metal compound, followed by a hydrazine-based compound, and then a second refractory metal compound. Alternatively, the nitride layer formation may start with the chemisorption of monolayers of either of the two refractory metal compounds onto the substrate followed by monolayers of the hydrazine-based compound. Optionally, monolayers of more than two refractory metal compounds may be chemisorbed on the substrate surface.

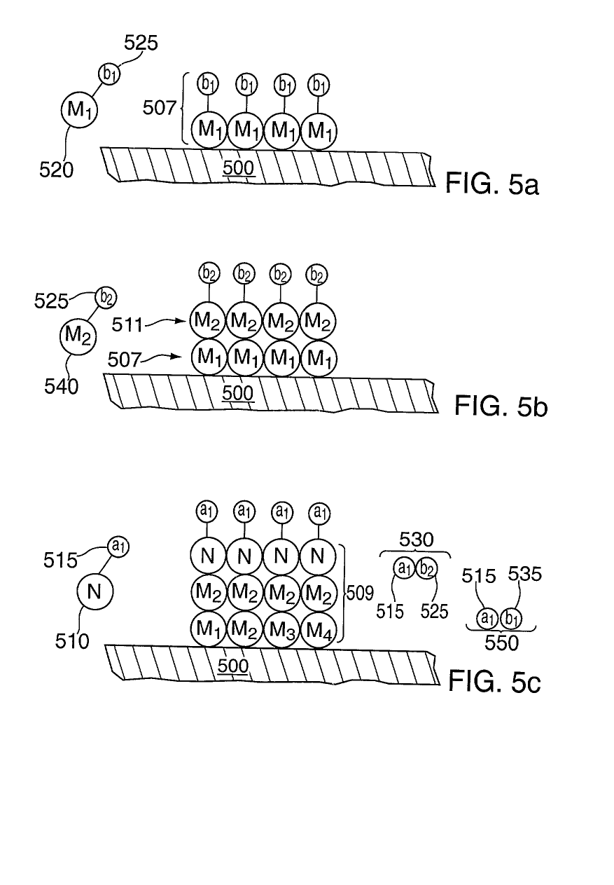

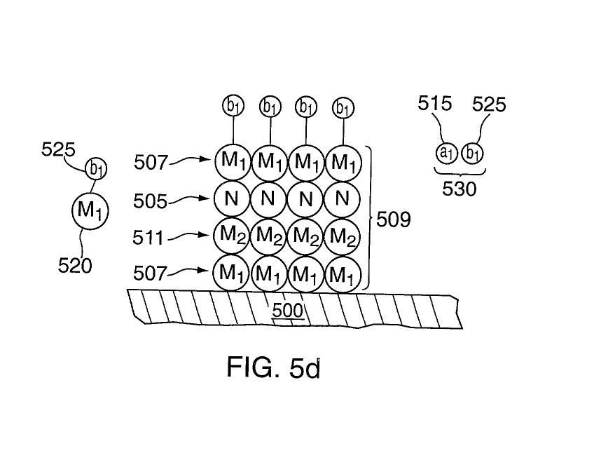

In a third chemisorption process, the hydrazine-based compound and two or more refractory metal compounds are alternately chemisorbed on the substrate to form a composite refractory metal layer, as illustrated in FIGS. 5a-5d. FIG. 5a depicts a cross-sectional view of a substrate 500, which may be in a stage of integrated circuit fabrication. A self-limiting monolayer of a first refractory metal compound 507 is chemisorbed on the substrate 500 by introducing a pulse of a first refractory metal compound M₁b₁ 507 into a process chamber similar to that shown in FIG. 1 according to the process conditions described above with reference to FIGS. 3a-3d. The first refractory metal compound M₁b₁ combines refractory metal atoms M₁ 520 with one or more reactive species b₁ 535.

After the monolayer of the first refractory metal compound 507 is chemisorbed onto the substrate 500, excess first refractory metal compound is removed from the process chamber by introducing a pulse of a purge gas thereto.

Referring to FIG. 5b, after the process chamber has been purged, a pulse of a second refractory metal compound M₂b₂ is introduced into the process chamber. A layer of the second refractory metal compound 511 is chemisorbed onto monolayer of the first refractory metal compound 507. The second refractory metal compound M₂b₂ combines refractory metal atoms M₂ 540 with one or more reactive species b₂ 525.

After the monolayer of the second refractory metal compound 511 is chemisorbed onto the monolayer of the first refractory metal compound 507, excess second refractory metal compound M₂b₂ is removed from the process chamber by introducing a pulse of the purge gas therein.

A pulse of a hydrazine-based compound is then introduced into the process chamber. A monolayer of the hydrazine-based compound 505 is chemisorbed on the second refractory metal monolayer 511, as shown in FIG. 5c. The hydrazine-based compound combines nitrogen atoms (N) 510 with one or more reactive species a₁ 515.

The chemisorbed monolayer of hydrazine-based compound 505 reacts with both the first refractory metal monolayer 507 as well as the second refractory metal monolayer 511 to form a composite refractory metal nitride layer 509. The reactive species a₁ 515, b₁ 535, and b₂ 525 form byproducts a₁b₂ 530 and a₁b₁ 550 that are transported from the substrate 500 surface by the vacuum system.

After the monolayer of the hydrazine-based compound 505 is chemisorbed onto the second refractory metal monolayer 511, excess hydrazine-based compound is removed from the process chamber by introducing a pulse of a purge gas therein.

Referring to FIG. 5d, the refractory metal nitride layer deposition sequence of alternating monolayers of the hydrazine-based compound and the two refractory metal compounds M₁b₁ and M₂b₁ are repeated until a desired refractory metal nitride layer thickness is achieved.

In FIGS. 5a-5d, refractory metal nitride layer formation is depicted as starting with the chemisorption of the first refractory metal monolayer on the substrate followed by monolayers of the second refractory metal compound and the hydrazine-based compound. Alternatively, the refractory metal nitride layer formation may start with the chemisorption of the monolayer of hydrazine-based compound on the substrate followed by the monolayers of the two refractory metal compounds. Optionally, monolayers of more than two refractory metal compounds may be chemisorbed on the substrate surface.

The sequential deposition processes described above advantageously provide good step coverage for the refractory metal nitride layer, due to the monolayer chemisorption mechanism used for forming such layer. In particular, refractory metal nitride layer formation using the monolayer chemisorption mechanism is believed to contribute to a near perfect step coverage over complex substrate topographies.

Furthermore, in chemisorption processes, since a monolayer may be adsorbed on the topographic surface, the size of the deposition area is largely independent of the amount of precursor gas remaining in the reaction chamber once a monolayer has been formed.

Referring to FIG. 2c, after the formation of the nitride layer 204, a contact layer 206 may be formed thereon to complete the interconnect structure. The contact layer 206 is preferably selected from the group of aluminum (Al), copper (Cu), tungsten (W), and combinations thereof.

The contact layer 206 may be formed, for example, using chemical vapor deposition (CVD), physical vapor deposition (PVD), or a combination of both CVD and PVD. For example, an aluminum (Al) layer may be deposited from a reaction of a gas mixture containing dimethyl aluminum hydride (DMAH) and hydrogen (H₂) or argon (Ar) or other DMAH containing compounds, a CVD copper layer may be deposited from a gas mixture containing Cu⁺²(hfac)₂ (copper hexafluoro acetylacetonate), Cu⁺²(fod)₂ (copper heptafluoro dimethyl octanediene), Cu⁺¹hfac TMVS (copper hexafluoro acetylacetonate trimethylvinylsilane), or combinations thereof, and a CVD tungsten layer may be deposited from a gas mixture containing tungsten hexafluoride (WF₆). A PVD layer is deposited from a copper target, an aluminum target, or a tungsten target.

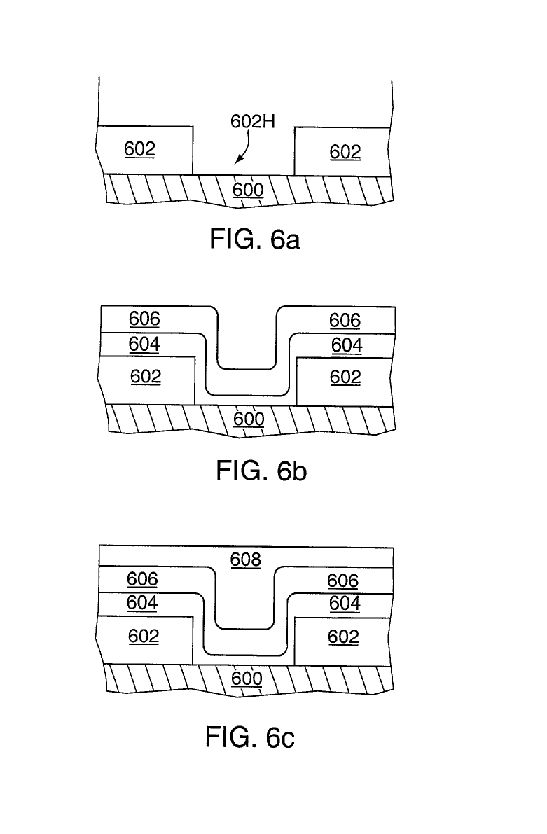

FIGS. 6a-6cillustrate an alternate embodiment of refractory metal layer formation for integrated circuit fabrication of an interconnect structure. In general, the substrate 600 refers to any workpiece upon which film processing is performed, and a substrate structure 650 is used to generally denote the substrate 600 as well as other material layers formed on the substrate 600. Depending on the specific stage of processing, the substrate 600 may be a silicon semiconductor wafer, or other material layer, which has been formed on the wafer. FIG. 6a, for example, shows a cross-sectional view of a substrate structure 650, having a material layer 602 thereon. In this particular illustration, the material layer 602 may be an oxide (e. g., silicon dioxide). The material layer 602 has been conventionally formed and patterned to provide a contact hole 602H extending to the top surface 600T of the substrate 600.

FIG. 6b shows two refractory metal nitride layers 604, 606 conformably formed on the substrate structure 650. The refractory metal nitride layers 604, 606 are formed by chemisorbing monolayers of a hydrazine-based compound and one or more refractory metal compounds on the substrate structure 650 as described above with reference to FIGS. 3a-3d. The two refractory metal nitride layers 604, 606 may each comprise one or more refractory metals. The thicknesses of the two refractory metal nitride layers 604, 606 may be varied depending on the specific stage of processing. Each refractory metal nitride layer 604, 606 may, for example, have a thickness in a range of about 200 Å to about 5000 Å.

Referring to FIG. 6c, after the formation of the two refractory metal nitride layers 604, 606, a contact layer 608 may be formed thereon to complete the interconnect structure. The contact layer 608 is preferably selected from the group of aluminum (Al), copper (Cu), tungsten (W), and combinations thereof.

The specific process conditions disclosed in the above discussion are meant for illustrative purposes only. Other combinations of process parameters such as precursor and inert gases, flow ranges, pressure and temperature may also be used in forming the nitride layer of the present invention.

Although several preferred embodiments, which incorporate the teachings of the present invention, have been shown and described in detail, those skilled in the art can readily devise many other varied embodiments that still incorporate these teachings.

What is claimed is:

1. A method of film deposition, comprising the step of:
(a) chemisorbing monolayers of a hydrazine-based compound and one or more refractory metal compounds on a substrate to form a refractory metal nitride layer thereon.

2. The method of claim 1 wherein the substrate is subjected to a purge gas following chemisorption of each monolayer.

3. The method of claim 1 wherein the hydrazine-based compound is selected from the group of hydrazine (N₂H₄), monomethyl hydrazine (CH₃N₂H₃), dimethyl hydrazine (C₂H₆N₂H₂), t-butylhydrazine (C₆H₂N₂H₂) phenylhydrazine (C₆H₅N₂H₃), 2,2′-azoisobutane ((CH₃)₆C₂N₂), ethylazide (C₂H₅N₃), as well as combinations thereof.

4. The method of claim 1 wherein the one or more refractory metal compounds comprise a refractory metal selected from the group of titanium (Ti), tungsten (W), vanadium (V), niobium (Nb), tantalum (Ta), zirconium (Zr), hafnium (Hf), chromium (Cr), and molybdenum (Mo).

5. The method of claim 4 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (TiI₄), titanium bromide (TiBr₄), tetrakis(dimethylamido)titanium (TDMAT), pentakis(dimethylamido)tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

6. The method of claim 1 wherein step (a) is performed at a temperature between about 20° C. and about 600° C.

7. The method of claim 1 wherein step (a) is performed at a pressure less than about 100 torr.

8. The method of claim 2 wherein the purge gas is selected from the group of helium (He), argon (Ar), hydrogen (H₂), nitrogen (N₂), ammonia (NH₃), and combinations thereof.

9. The method of claim 1 wherein monolayers of the hydrazine-based compound and the one or more refractory metal compounds are alternately chemisorbed on the substrate.

10. The method of claim 9 wherein one monolayer of the hydrazine-based compound is chemisorbed on the substrate between each chemisorbed monolayer of the one or more refractory metal compounds.

11. The method of claim 10 wherein the hydrazine-based compound is chemisorbed on the substrate prior to the one or more refractory compounds.

12. The method of claim 10 wherein one of the one or more refractory metal compounds is chemisorbed on the substrate prior to the hydrazine-based compound.

13. The method of claim 9 wherein one monolayer of the hydrazine-based compound is chemisorbed on the substrate after two or more monolayers of the one or more refractory metal compounds are chemisorbed thereon.

14. The method of claim 9 wherein two or more monolayers of the one or more refractory metal compounds are chemisorbed on the substrate after one monolayer of the hydrazine-based compound is chemisorbed thereon.

15. A method of forming a barrier layer structure for use in integrated circuit fabrication, comprising the steps of:
(a) providing a substrate having an oxide layer thereon, wherein the oxide layer has apertures formed therein to a top surface of the substrate; and
(b) forming at least one refractory metal nitride layer on at least portions of the oxide layer and the substrate surface, wherein the at least one refractory metal nitride layer is formed using a sequential chemisorption process.

16. The method of claim 15 wherein the at least one refractory metal nitride layer comprises one or more refractory metals.

17. The method of claim 16 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

18. The method of claim 15 wherein the sequential chemisorption process of step (b) comprises the step of:
(c) chemisorbing monolayers of a hydrazine-based compound and one or more refractory metal compounds on the substrate to form the refractory metal nitride layer thereon.

19. The method of claim 18 wherein the substrate is subjected to a purge gas following chemisorption of each monolayer.

20. The method of claim 18 wherein the hydrazine-based compound is selected from the group of hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

21. The method of claim 18 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (TiI₄), titanium bromide (TiBr₄), tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

22. The method of claim 18 wherein step (c) is performed at a temperature between about 20° C. and about 600° C.

23. The method of claim 18 wherein step (c) is performed at a pressure less than about 100 torr.

24. The method of claim 19 wherein the purge gas is selected from the group of helium (He), argon (Ar), hydrogen (H₂), nitrogen (N₂), ammonia (NH₃), and combinations thereof.

25. The method of claim 18 wherein monolayers of the hydrazine-based compound and the one or more refractory metal compounds are alternately chemisorbed on the substrate.

26. The method of claim 25 wherein one monolayer of the hydrazine-based compound is chemisorbed on the substrate between each chemisorbed monolayer of the one or more refractory metal compounds.

27. The method of claim 26 wherein the hydrazine-based compound is chemisorbed on the substrate prior to the one or more refractory compounds.

28. The method of claim 26 wherein one of one or more refractory metal compounds is chemisorbed on the substrate prior to the hydrazine-based compound.

29. The method of claim 25 wherein one monolayer of the hydrazine-based compound is chemisorbed on the substrate after two or more monolayers of the one or more refractory metal compounds are chemisorbed thereon.

30. The method of claim 25 wherein two or more monolayers of the one or more refractory metal compounds are chemisorbed on the substrate after one monolayer of the hydrazine-based compound is chemisorbed thereon.

31. A computer storage medium containing a software routine that, when executed, causes a general purpose computer to control a deposition chamber using a method of thin film deposition comprising the step of:
(a) forming a refractory metal nitride layer on a substrate, wherein the refractory metal nitride layer is formed using a sequential chemisorption process.

32. The computer storage medium of claim 31 wherein the at least one refractory metal nitride layer comprises one or more refractory metals.

33. The computer storage medium of claim 32 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

34. The computer storage medium of claim 31 wherein the sequential chemisorption process of step (a) comprises the step of:
(b) chemisorbing monolayers of a hydrazine-based compound and one or more refractory metal compounds on the substrate to form the refractory metal nitride layer thereon.

35. The computer storage medium of claim 34 wherein the substrate is subjected to a purge gas following chemisorption of each monolayer.

36. The computer storage medium of claim 34 wherein the hydrazine-based compound is selected from the group of hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃) ₆C₂N₂), ethylazide (C₂H₅N₃), as well as combinations thereof.

37. The computer storage medium of claim 34 wherein the one or more refractory metal compounds are selected from the group of titanium tetrachloride (TiC1₄), tungsten hexafluoride (WF₆), tantalum pentachloride (TaCl₅), zirconium tetrachloride (ZrCl₄), hafnium tetrachloride (HfC₄), molybdenum pentachloride (MoCl₅), niobium pentachloride (NbCl₅), vanadium pentachloride (VCl₅), chromium tetrachloride (CrCl₄), titanium iodide (TiI₄), titanium bromide (TiBr₄), tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

38. The computer storage medium of claim 34 wherein step (b) is performed at a temperature between about 20° C. and about 600° C.

39. The computer storage medium of claim 34 wherein step (b) is performed at a pressure less than about 100 torr.

40. The computer storage medium of claim 35 wherein the purge gas is selected from the group of helium (He), argon (Ar), hydrogen (H₂), nitrogen (N₂), ammonia (NH₃), and combinations thereof.

41. The computer storage medium of claim 34 wherein monolayers of the hydrazine-based compound and the one or more refractory metal compounds are alternately chemisorbed on the substrate.

42. The computer storage medium of claim 41 wherein one monolayer of the hydrazine-based compound is chemisorbed on the substrate between each chemisorbed monolayer of the one or more refractory metal compounds.

43. The computer storage medium of claim 42 wherein the hydrazine-based compound is chemisorbed on the substrate prior to the one or more refractory metal compounds.

44. The computer storage medium of claim 42 wherein one of the one or more refractory metal compounds is chemisorbed on the substrate prior to the hydrazine-based compound.

45. The computer storage medium of claim 41 wherein one monolayer of the hydrazine-based compound is chemisorbed on the substrate after two or more monolayers of the one or more refractory metal compounds are chemisorbed thereon.

46. The computer storage medium of claim 41 wherein two or more monolayers of the one or more refractory metal compounds are chemisorbed on the substrate after one monolayer of the hydrazine-based compound is chemisorbed thereon.

47. A device comprising:
at least one refractory metal nitride layer formed on a substrate, wherein one of the at least one refractory metal nitride layers comprises two or more refractory metals.

48. The device of claim 47 wherein the two or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

49. A device comprising:
a substrate having an oxide layer thereon, wherein the oxide layer has an aperture formed therein to a top surface of the substrate; and
at least one refractory metal nitride layer formed on portions of the oxide layer and the substrate surface, wherein one of the at least one refractory metal nitride layers comprises two or more refractory metals.

50. The device of claim 49 wherein the two or more refractory metals are selected from the group of titanium (Ti), tungsten (W), vanadium (V), niobium (Ni), tantalum (Ta), zirconium (Zr), hafnium (Hf), chromium (Cr), and molybdenum (Mo).

51. An interconnect structure, comprising:
a substrate having an oxide layer thereon, wherein the oxide layer has apertures formed therein to a top surface of the substrate;
a first refractory metal nitride layer formed on portions of the oxide layer and the substrate surface, wherein the first refractory metal nitride layer comprises one or more refractory metals; and
a second refractory metal nitride layer formed on the first refractory metal nitride layer, wherein the second refractory metal nitride layer comprises one or more refractory metals.

52. The interconnect structure of claim 51 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

53. The interconnect structure of claim 51 wherein the first refractory metal nitride layer has a thickness less than about 100 Å (Angstroms).

54. The interconnect structure of claim 51 wherein the second refractory metal nitride layer has a thickness in a range of about 100 Å to about 1000 Å.
